(19) United States
(12) Patent Application Publication
(10) Pub. No.: US 2013/0242281 A1
(43) Pub. Date: Sep. 19, 2013

(54) EXPOSURE APPARATUS

(71) Applicant: V TECHNOLOGY CO., LTD., Kanagawa (JP)

(72) Inventor: Michinobu MIZUMURA, Kanagawa (JP)

(73) Assignee: V TECHNOLOGY CO., LTD., Kanagawa (JP)

(21) Appl. No.: 13/890,714

(22) Filed: May 9, 2013

(30) Foreign Application Priority Data
Nov. 12, 2010 (JP) 2010-253416

(51) Int. Cl. G03F 7/20

(52) U.S. Cl. CPC G03F 7/70191
USPC 355/71

(57) ABSTRACT

An exposure apparatus includes a pattern generator with light switches arrayed on a plane parallel to a surface of an object to be exposed. Each of the light switches has a switching element that is a rectangular pillar of an electro-optic crystal, and a pair of polarizers arranged on respective sides in the long axis direction of the switching element. The exposure apparatus drives the light switches individually to generate an exposure pattern having a certain bright and dark form and irradiate the object to be exposed with the pattern. Furthermore, the exposure apparatus has a plurality of microlenses provided on the light-output side of the pattern generator so that the optical axes of the microlenses are aligned to the longitudinal center axes of the switching elements, so as to project images of light-output ends of the switching elements at reduced size onto the object to be exposed.

This application is a continuation application of PCT/JP2011/073840, filed on Oct. 17, 2011.

### BACKGROUND OF THE INVENTION

1. Field of the Invention

The present invention relates to a maskless exposure apparatus which includes a pattern generator for optically modulating source light to produce exposure patterns of bright and dark and carries out exposure, and in particular, relates to an exposure apparatus capable of easily expanding an exposure area.

2. Description of Related Art

Conventionally, such an exposure apparatus employs a digital micromirror device as a pattern generator, which has a plurality of two-dimensionally arranged micromirrors, each capable of adjusting reflection angle, to optically modulate source light to generate exposure patterns of bright and dark, and irradiates an object to be exposed with such an exposure pattern via an objective lens (for example, refer to Japanese Patent Application Laid-open (Kokai) Publication No. 2010-141245).

However, in such a conventional exposure apparatus, in order to expand an exposure area on an object to be exposed, it is necessary to produce a new digital micromirror device having a larger area in which the number of micromirrors is increased, and to enlarge the size of an objective lens. Considering production costs of such a micromirror device, aberration of the lens and production costs of the lens, expansion of the exposure area is limited.

### SUMMARY OF THE INVENTION

Under these circumstances, it is an object of the present invention to address such a problem and to provide an exposure apparatus which can easily achieve expansion of an exposure area.

In order to achieve the above object, the exposure apparatus of the present invention includes a pattern generator having a plurality of light switches arrayed on a plane parallel to a surface of an object to be exposed. The plurality of light switches each includes: a switching element that is a rectangular pillar of an electro-optical crystal provided with respective electrodes on opposing surfaces of the pillar parallel to a long axis of the pillar; and a pair of polarizers arranged on respective end sides in the long axis direction of the switching element so as to form a crossed-Nichol arrangement across the switching element. The exposure apparatus is configured to drive the plurality of light switches individually to generate an exposure pattern having a certain bright and dark form and irradiate the object to be exposed with the pattern. The exposure apparatus further includes a plurality of microlenses provided on the light-output side of the pattern generator so that the optical axes of the microlenses are aligned to the longitudinal center axes of the switching elements, so as to project images of light-output end faces of the switching elements at reduced size onto the object to be exposed.

By the configuration described above, a pattern generator includes a plurality of light switches arrayed on a plane parallel to a surface of an object to be exposed, and the plurality of light switches each includes: a switching element that is a rectangular pillar of an electro-optical crystal provided with respective electrodes on opposing surfaces of the pillar parallel to a long axis of the pillar; and a pair of polarizers arranged on respective end sides in the long direction of the switching element so as to form a crossed-Nichol arrangement across the switching element. The light switches are driven individually to generate an exposure pattern having a certain bright and dark form. Furthermore, by a plurality of microlenses provided on the light-output side of the pattern generator so that the optical axes of the microlenses are aligned to the longitudinal center axes of the switching elements, images of light-output end faces of the switching elements are projected at reduced size onto the object to be exposed.

Furthermore, the pair of polarizers is a pair of polarizers arranged so that their polarization planes are rotated by 90 degrees from each other about an optical axis of the light switch. By this configuration, linearly polarized light is extracted by the polarizer arranged on the light-input end side of the switching element, and output of light from the light switch is limited by the polarizer arranged on the light-output end side of the switching element according to the ON and OFF drive state of the switching element.

Furthermore, the pair of polarizers is a pair of polarizers arranged so that their polarizing axes are rotated by 90 degrees from each other about an optical axis of the light switch. By this configuration, linearly polarized light is extracted by the polarizer arranged on the light-input end side of the switching element, and output of light from the light switch is limited by the polarizer arranged on the light-output end side of the switching element according to ON and OFF drive state of the switching element.

Moreover, the exposure apparatus has a stage system for scanning the object to be exposed at a constant speed. By this configuration, the object to be exposed is exposed while it is scanned at a constant speed by the stage system.

The plurality of light switches are located in at least two rows in a direction across the scanning direction of the object to be exposed at a constant pitch, so that intervals between exposure patterns, that are created by upstream side light switches in the scanning direction of the object to be scanned in the plurality of light switches, are filled by exposure patterns created by downstream side light switches in the plurality of light switches. By this configuration, while the object to be exposed is scanned in a fixed direction, intervals between exposure patterns, that are created by upstream side light switches in the scanning direction of the object to be scanned in the plurality of light switches located in at least two rows in a direction across the scanning direction of the object to be exposed at a constant pitch, are filled by exposure patterns created by downstream side light switches in the plurality of light switches, and the object to be exposed is exposed.

According to a first aspect of the present invention, it is possible to expand the exposure area simply by arranging a plurality of pattern generators and a plurality of microlens substrates having fixed sizes. In this case, even when the plurality of pattern generators are arranged, there is no need to increase the size of the lens in a manner different from conventional techniques, and accordingly, it is possible to easily expand the exposure area without having the problem of lens aberration. Furthermore, since it is only necessary to prepare pattern generators and microlens substrates that are standardized and have fixed sizes, it is possible to reduce increases in production costs of elements,

Furthermore, according to a second aspect of the present invention, it is possible to form a film for separating source light into two linearly polarized light components of P waves and S waves, respectively, and the film is made of an inorganic material. Accordingly, even if the separation film is irradiated with source light having high thermal energy, it is possible to suppress burn out of the separation film. Accordingly, it is possible to employ a light source having high intensity and to reduce a tact time of an exposure step.

Furthermore, according to a third aspect of the present invention, it is possible to reduce the thickness of the pattern generator and to reduce the production cost.

Furthermore, according to a fourth aspect of the present invention, it is possible to expose the object to be exposed while it is continuously scanned, and to further reduce the tact time of the exposure step.

Furthermore, according to a fifth aspect of the present invention, it is possible to form a dense exposure pattern. Accordingly, it is possible to form an exposure pattern having a complex shape with high accuracy.

### BRIEF DESCRIPTION OF THE DRAWINGS

FIG. 1 is a front view illustrating an embodiment of an exposure apparatus of the present invention.

FIG. 2 is a perspective view illustrating the construction of a light switch of a pattern generator employed in the exposure apparatus of the present invention.

FIG. 3 is a plan view illustrating an arrangement example of switching elements constituting the above pattern generator.

FIGS. 4A and 4B are explanation views illustrating operation of the switching element, wherein FIG. 4A shows ON-operation, and FIG. 4B shows OFF-operation.

FIG. 5 is an enlarged front view of an essential part of the exposure apparatus of the present invention.

FIG. 6 is an explanation view illustrating exposure by the exposure apparatus of the present invention.

### DETAILED DESCRIPTION OF THE PREFERRED EMBODIMENTS

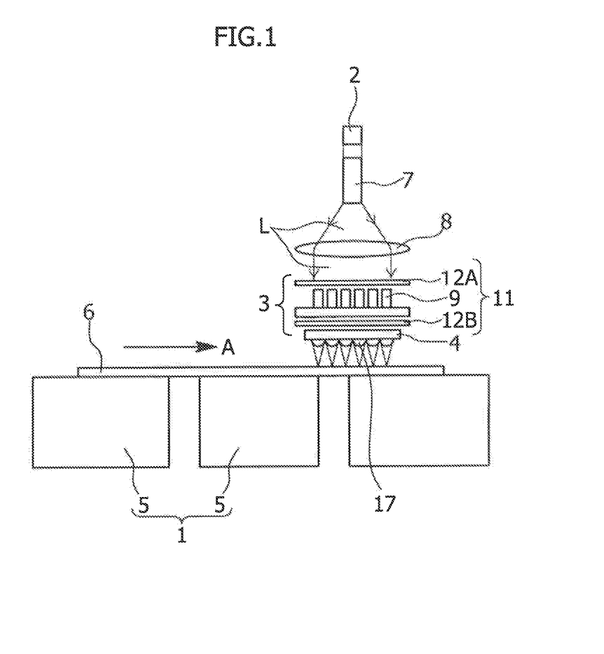

Hereinbelow, embodiments of the present invention will be described in detail with reference to attached drawings. FIG. 1 is a front view illustrating an embodiment of an exposure apparatus of the present invention. This exposure apparatus is configured to optically modulate source light by using a pattern generator to generate an exposure pattern of bright and dark form and to carry out exposure. The apparatus includes a stage system 1, a light source 2, a pattern generator 3 and a microlens substrate 4.

The stage system 1 is configured to scan an object to be exposed 6, which is placed on an upper surface of a stage 5, in the direction indicated by an arrow A at a constant speed. For example, while the object to be exposed 6 is lifted a constant amount off an upper surface of a stage 5 by air blown and drawn by the stage 5, both edges of the object to be exposed 6 in the direction indicated by an arrow A are held by a moving mechanism, not shown, and the object to be exposed 6 is scanned by the moving mechanism.

Above the stage system 1, a light source 2 is provided. This light source 2 emits ultraviolet light as source light L, and for example, it is a super high pressure mercury lamp, a xenon lamp, or an ultraviolet-irradiating laser. The intensity distribution of the source light L irradiated from the light source 2, in a cross-section perpendicular to the optical axis, is equalized by e.g. an optical integrator 7 such as a fly eye lens or a rod lens, and thereafter, the source light L is transformed into parallel light by a condenser lens 8 and irradiated by a pattern generator 3, to be described later.

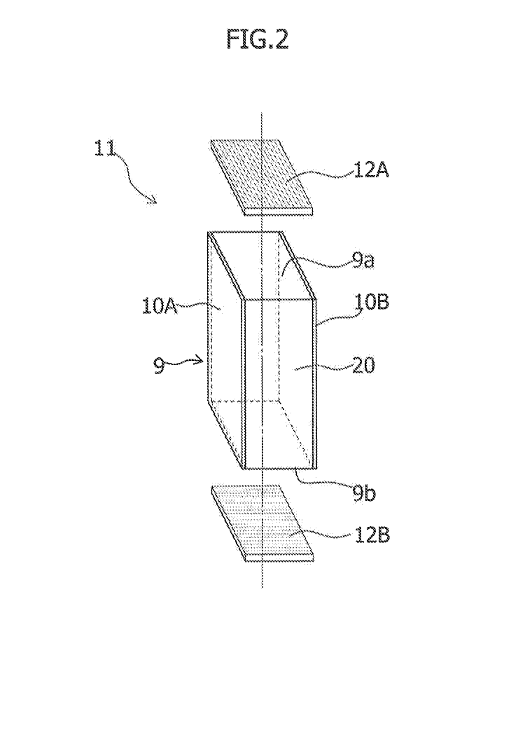

In the forward direction in the light irradiation direction of the light source 2, a pattern generator 3 is provided. This pattern generator 3 is configured to generate an exposure pattern of bright and dark form to be irradiated on the object to be exposed 6, and as illustrated in FIG. 2, the pattern generator 3 includes a plurality of light switches 11 arranged on a plane parallel to a surface of the object to be exposed 6, and the plurality of light switches each has: a switching element 9 that is a rectangular pillar 20 of an electro-optical crystal provided with respective electrodes 10A and 10B on opposing surfaces of the pillar parallel to a long axis of the pillar; and a pair of polarizers, such as a pair of polarizing beam splitters or a pair of polarizers, arranged on respective sides, that are light-input end 9a and light-output end 9b, in the long axis direction of the switching element 9 so as to form a crossed-Nichol arrangement across the switching element 9. In this embodiment, a case of employing polarizers 12A and 12B will be described.

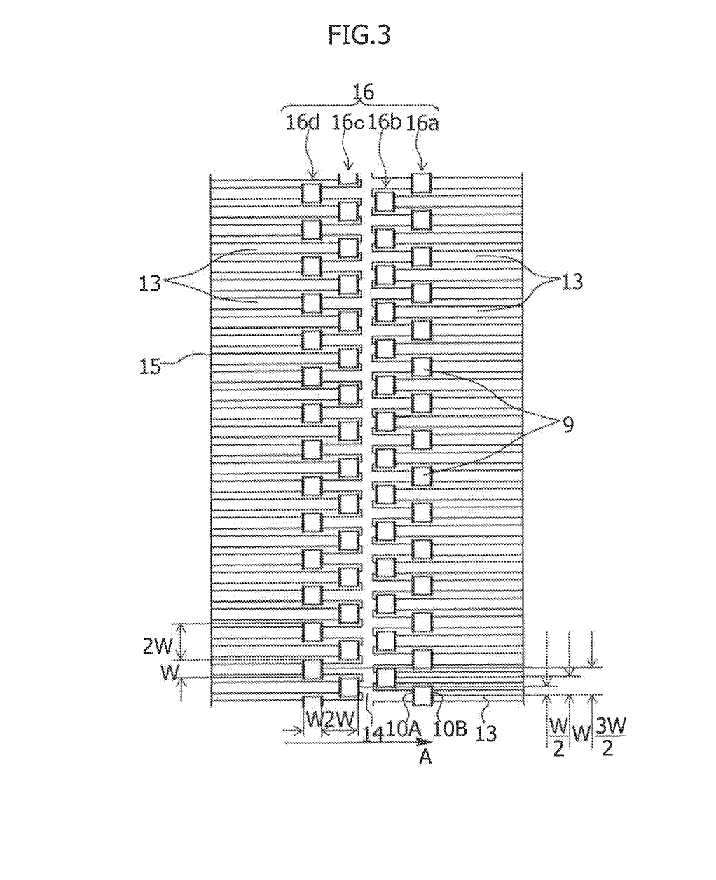

FIG. 3 is a plan view illustrating an arrangement example of a plurality of switching elements 9. The plurality of switching elements 9 each has an end face formed into a square shape having vertical and horizontal widths of W, and on a transparent substrate such as a wiring substrate 15 made of the same electro-optical material on which drive wirings 13 and ground wirings 14 are formed, the switching elements are arranged in a row with an arrangement pitch of 2 W in a direction across the scanning direction (hereinafter such a scanning direction is referred to as “substrate-scanning direction”) of the object to be exposed 6 indicated by the arrow A so that each electrode 10A contacts such a ground wiring 14 and each electrode 10B contacts such a drive wiring 13, to form a switching element row 16. Four such switching element rows 16 are formed in parallel with an arrangement pitch of 2 W in the substrate-scanning direction so that respective switching elements 9 of adjacent switching element rows 16 are staggered to each other by nW/2 (n is an integer of at least 1) in the direction across the substrate-scanning direction, so that intervals between exposure patterns created by upstream side switching elements 9 in the substrate-scanning direction can be filled by exposure patterns created by downstream side switching elements 9.

FIG. 3 illustrates a case in which with respect to an upstream side switching element row 16a, downstream side switching element rows 16b, 16c and 16d are staggered by W, W/2 and 3 W/2, respectively, in the direction across the substrate-scanning direction.

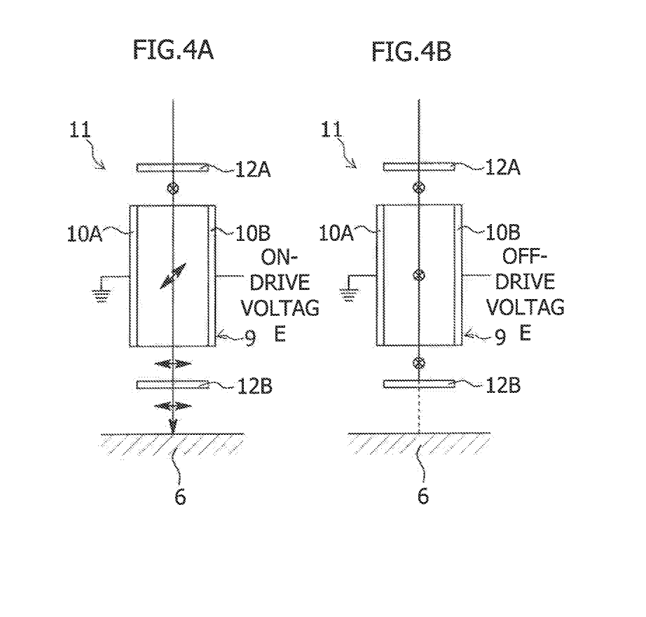

In each light switch 11 of the pattern generator 3 thus configured, as illustrated in FIG. 4A, when an ON-drive voltage is applied to the electrode 10B to drive the light switch 11 ON, a polarized wave face of a linearly polarized light that has been transmitted through a light-input side polarizer 12A is rotated by 90 degrees when the light passes through the switching element 9. Accordingly, in this case, the linearly polarized light that has passed the switching element 9 can be transmitted through a polarizer 12B, that is arranged in a crossed-Nichol arrangement with the above polarizer 12A, and the linearly polarized light is irradiated on an object to be exposed 6, and the object to be exposed 6 can be exposed.

On the other hand, as illustrated in FIG. 4B, when an OFF-drive voltage is applied to the electrode 10B to turn the light switch 11 OFF, the polarized wave face of the linearly polarized light that has been transmitted through a light-input side polarizer 12A is not rotated when the light passes through the switching element 9, and accordingly, the light is stopped by the light output side polarizer 12B. Accordingly, in this case, the linearly polarized light cannot reach the object to be exposed 6 and the object to be exposed 6 cannot be exposed. Thus, by appropriately driving a plurality of light switches 11 ON-OFF, it is possible to generate an exposure pattern of desired bright and dark form and to expose the object to be exposed 6.

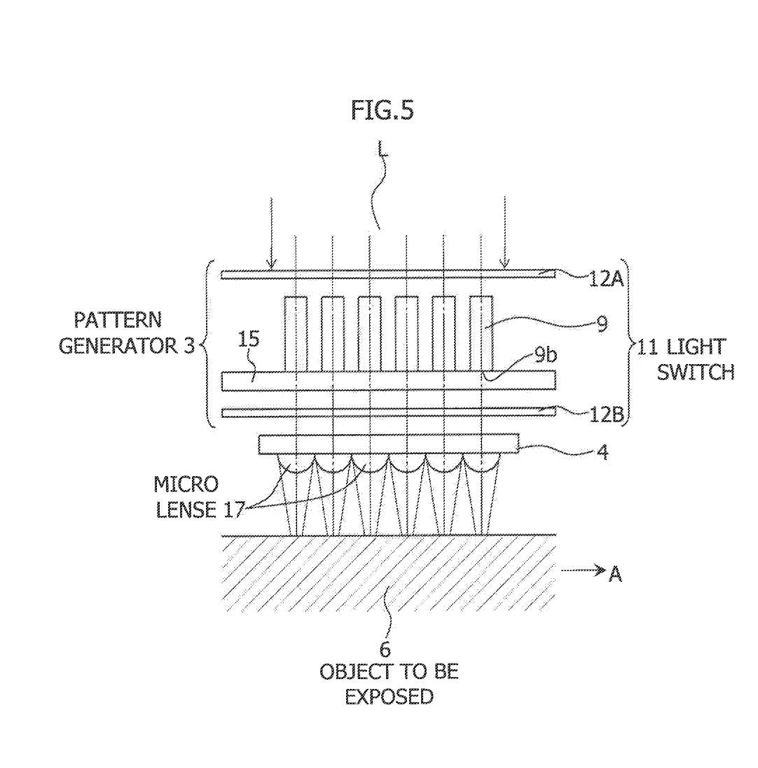

On the light-output side of the pattern generator 3, a microlens substrate 4 is disposed in proximity. This microlens substrate 4 has, as illustrated in FIG. 5, a plurality of microlenses 17 provided so that their optical axes are aligned to longitudinal center axes of the switching elements 9 of the light switches 11, and is configured so that each microlens 17 projects at reduced size an image of a light-output end face of a corresponding switching element 9 onto the object to be exposed 6.

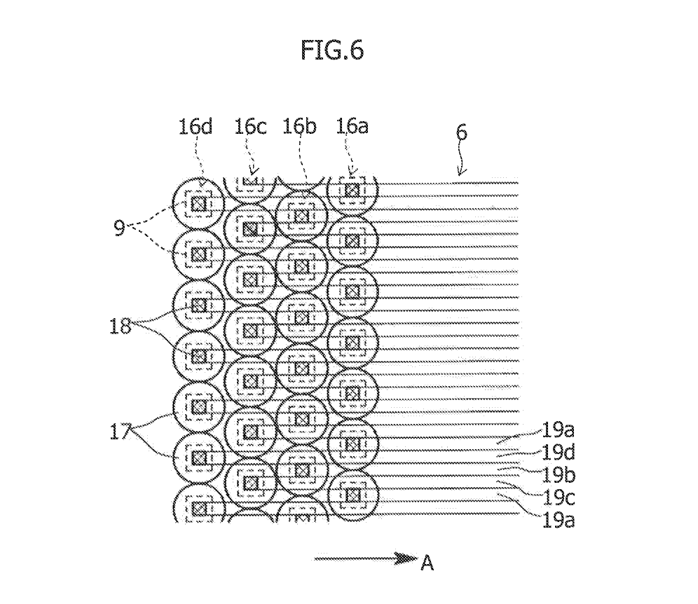

FIG. 6 is an explanation view illustrating reduced-size projected images of end faces of switching elements 9 of light switches 11 of the microlenses 17. In this embodiment, the figure shows projection images 18 of which each size is a quarter size of the light-output end face 9b of each switching element 9 by each microlens 17. It is understandable from the figure that intervals between exposure patterns 19a created by an upstream side switching element row 16a in the substrate-scanning direction indicated by an arrow A can be filled by exposure patterns 19b, 19c and 19d created by downstream side three switching element rows 16b, 16c and 16d, respectively,

Next, operation of an exposure apparatus having such a construction will be described.

A stage system 1 is scanning an object to be exposed 6 placed on a stage 5 in the substrate-scanning direction indicated by the arrow A at a constant speed. In this state, an image of the object to be exposed 6 is captured from above by a line camera, not shown, which is disposed on the upstream side the pattern generator 3 in the substrate-scanning direction and which has a plurality of light-receiving elements linearly arranged in the direction across the substrate-scanning direction, and the captured image is processed by a control means, not shown, to detect an alignment fiducial marker that has been provided on the object to be exposed 6 in advance.

Subsequently, the position of the alignment fiducial marker in the direction across the substrate-scanning direction is detected, the distance between the fiducial marker and an image-capturing center of the line camera is measured, and a position displacement of the fiducial marker from its target position is computed. Then, the pattern generator 3 is moved in the direction across the substrate-scanning direction so as to cancel the position displacement, to thereby align the pattern generator 3 to the object to be exposed 6. Here, since the horizontal distance between the image-capturing center of the line camera and an alignment fiducial marker of the pattern generator 3 in the direction across the substrate-scanning direction is stored in advance, it is possible to perform a position alignment between the object to be exposed 6 and the pattern generator 3 based on the position displacement computed above. Thus, it is possible to make the pattern generator 3 follow the object to be exposed 6 that is swinging in the left-right direction while it is moving.

When the object to be exposed 6 moves and an upstream side region of an exposure area in the substrate-scanning direction reaches a position right under a switching element row 16d of the pattern generator 3, light switches 9 of the pattern generator 3 are ON-OFF driven according to CAD data stored in advance, to generate an exposure pattern of bright and dark form. This exposure pattern is projected onto the object to be exposed 6 by the microlenses 17 of the microlens substrate 4, and consequently, on the object to be exposed 6, as illustrated in FIG. 6, reduced-size projected images 18 of light-output end faces 9b of the switching elements 9 are created.

Thereafter, each light switch 9 of the pattern generator 3 is appropriately driven at predetermined time intervals according to the CAD data, to irradiate exposure light on the object to be exposed 6 moving in the direction of the arrow A, and as illustrate in FIG. 6, exposure is carried out while intervals between exposure patterns 19a created by the upstream side switching element row 16a in the substrate-scanning direction indicated by the arrow A can be filled by exposure patterns 19b, 19c and 19d created by downstream side three switching element rows 16b, 16c and 16d, respectively.

Here, the width of the exposure area in the direction across the substrate-scanning direction can be expanded by arranging a plurality of pattern generators 3 and microlens substrates 4 in the direction across the substrate-scanning direction linearly or in a staggered form in two rows. Accordingly, even if the number of light switches 9 is increased, there is no need to increase the size of the lens, and it is possible to expand the exposure area without having the problem of lens aberration. Furthermore, since it is only necessary to prepare pattern generators 3 and microlens substrates 4 having fixed sizes, it is possible to reduce increases in production costs of the elements.

It should be noted that the entire contents of Japanese Patent Application No. 2010-253416, filed on Nov. 12, 2010, on which the convention priority is claimed is incorporated herein by reference.

It should also be understood that many modifications and variations of the described embodiments of the invention will occur to a person having an ordinary skill in the art without departing from the spirit and scope of the present invention as claimed in the appended claims.

What is claimed is

1. An exposure apparatus comprising
a pattern generator that includes a plurality of light switches arrayed on a plane parallel to a surface of an object to be exposed,
the plurality of light switches each having:
a switching element that is a rectangular pillar of an electro-optical crystal provided with respective electrodes on opposing surfaces of the pillar parallel to a long axis of the pillar; and
a pair of polarizers arranged on respective end sides in the long axis direction of the switching element so as to form a crossed-Nichol arrangement across the switching element,
the exposure apparatus being configured to drive the plurality of light switches individually to generate an exposure pattern having a certain bright and dark form and irradiate the object to be exposed with the pattern, and
the exposure apparatus further comprising a plurality of microlenses provided on the light-output side of the pattern generator so that the optical axes of the microlenses are aligned to the longitudinal center axes of the switching elements, so as to project images of light-output end faces of the switching elements at reduced size onto the object to be exposed.

2. The exposure apparatus according to claim 1, wherein the pair of polarizers is a pair of polarizers arranged so that their polarization planes are rotated by 90 degrees from each other about an optical axis of the light switch.

3. The exposure apparatus according to claim 1, wherein the pair of polarizers is a pair of polarizers arranged so that their polarizing axes are rotated by 90 degrees from each other about an optical axis of the light switch.

4. The exposure apparatus according to claim 1, which further comprises a stage system for scanning the object to be exposed in a fixed direction at a constant speed.

5. The exposure apparatus according to claim 4, wherein the plurality of light switches are located in at least two rows in a direction across the scanning direction of the object to be exposed at a constant pitch, so that intervals between exposure patterns, that are created by upstream side light switches in the scanning direction of the object to be exposed in the plurality of light switches, are filled by exposure patterns created by downstream side light switches in the plurality of light switches.
